(19) United States
(12) Patent Application Publication
(10) Pub. No.: US 2025/0079317 A1
(43) Pub. Date: Mar. 6, 2025

(54) SEMICONDUCTOR PACKAGE INCLUDING A REDISTRIBUTION STRUCTURE

(71) Applicant: SAMSUNG ELECTRONICS CO., LTD., SUWON-SI (KR)

(72) Inventors: Changyeon SONG, Suwon-si (KR); Dongwon KANG, Suwon-si (KR); Sunguk LEE, Suwon-si (KR); Jaeean LEE, Suwon-si (KR); Gyujin CHOI, Suwon-si (KR)

(21) Appl. No.: 18/813,120

(22) Filed: Aug. 23, 2024

(30) Foreign Application Priority Data
Aug. 31, 2023 (KR) 10-2023-0115604

(51) Int. Cl. H01L 23/532; H01L 23/14; H01L 23/522; H01L 23/528

(52) U.S. Cl. CPC H01L 23/53295; H01L 23/142; H01L 23/5226; H01L 23/5283

(57) ABSTRACT

A semiconductor package according to an embodiment includes a first substrate having an upper surface and a lower surface and a cavity extending from the upper surface to the lower surface; a first chip mounted in the cavity; a first redistribution structure disposed on the first chip; a passive element mounted inside the first redistribution structure; and an adhesive layer disposed below the passive element. The first redistribution structure includes a plurality of redistribution insulating layers stacked in a vertical direction on the first chip, and a first redistribution pattern and a second redistribution pattern located within the redistribution insulating layers. The first redistribution pattern is disposed below a recess vertically penetrating at least one redistribution insulating layer among the plurality of redistribution insulating layers. The second redistribution pattern is adjacent to the recess in a lateral direction.

### CROSS-REFERENCE TO RELATED APPLICATION

This application claims priority under 35 U.S.C. § 119 to Korean Patent Application No. 10-2023-0115604, filed on Aug. 31, 2023, in the Korean Intellectual Property Office, the disclosure of which is incorporated by reference herein in its entirety.

### 1. TECHNICAL FIELD

The inventive concept relates to a semiconductor package, and more specifically, to a semiconductor package including a redistribution structure.

### 2. DISCUSSION OF THE RELATED ART

As the demand for portable devices grows, there is a continuous demand for miniaturization and lightening of electronic components mounted on electronic products. Accordingly, semiconductor packages mounted on the electronic products are needed to process high-capacity data and minimize defects all while having an increasingly small volume.

### SUMMARY

The inventive concept provides semiconductor packages with improved reliability.

According to an aspect of the inventive concept, there is provided a semiconductor package including a first substrate having an upper surface and a lower surface and a cavity extending from the upper surface to the lower surface; a first chip mounted in the cavity; a first redistribution structure disposed on the first chip; a passive element mounted inside the first redistribution structure; and an adhesive layer disposed below the passive element. The first redistribution structure includes a plurality of redistribution insulating layers stacked in a vertical direction on the first chip, and a first redistribution pattern and a second redistribution pattern located within the redistribution insulating layers. The first redistribution pattern is disposed below a recess vertically penetrating at least one redistribution insulating layer among the plurality of redistribution insulating layers. The second redistribution pattern is adjacent to the recess in a lateral direction.

According to another aspect of the inventive concept, there is provided a semiconductor package including a first substrate with a cavity extending from an upper surface of the first substrate to a lower surface of the first substrate; a first chip mounted in the cavity; a first redistribution structure disposed on the first substrate and the first chip; a passive element mounted inside the first redistribution structure; and an adhesive layer disposed below the passive element. The first redistribution structure includes a plurality of redistribution insulating layers stacked in a vertical direction on the first chip, a first redistribution pattern and a second redistribution pattern disposed within the redistribution insulating layers, and a first insulating layer covering an uppermost redistribution insulating layer among the plurality of redistribution insulating layers and the passive element. The first redistribution pattern is disposed below a recess vertically penetrating at least one redistribution insulating layer among the plurality of redistribution insulating layers. The second redistribution pattern is disposed adjacent to the recess in a lateral direction. An upper surface of the passive element is disposed at a lower level than an upper surface of the uppermost redistribution insulating layer.

According to an aspect of the inventive concept, there is provided a semiconductor package including a first substrate with a cavity extending from an upper surface of the first substrate to a lower surface of the first substrate; a first chip mounted in the cavity; a first redistribution structure disposed on the first substrate and the first chip; a passive element mounted inside the first redistribution structure; an adhesive layer disposed below the passive element; and a second redistribution structure disposed below the first substrate. The first redistribution structure includes a plurality of redistribution insulating layers stacked in a vertical direction on the first chip, a first redistribution pattern and a second redistribution pattern disposed within the redistribution insulating layers, and a first insulating layer covering an uppermost redistribution insulating layer among the plurality of redistribution insulating layers and the passive element. The first redistribution pattern is disposed below a recess vertically penetrating in at least one redistribution insulating. The second redistribution pattern is disposed adjacent to the recess. An upper surface of the passive element is disposed at a lower level than an upper surface of the uppermost redistribution insulating layer among the plurality of redistribution insulating layers. A width of the recess is from about 500 μm to about 900 μm, and a depth of the recess is from about 100 μm to about 200 μm.

### BRIEF DESCRIPTION OF THE DRAWINGS

Embodiments of the inventive concept will be more clearly understood from the following detailed description taken in conjunction with the accompanying drawings in which:

FIG. 1 is a schematic cross-sectional view of a semiconductor package according to an embodiment;

FIG. 2 is a schematic cross-sectional view of a semiconductor package according to an embodiment;

FIG. 3 is a schematic cross-sectional view of a semiconductor package according to an embodiment, and

FIGS. 4, 5, 6, 7, 8, 9, 10, 11, 12 and 13 are schematic cross-sectional views illustrating a method of manufacturing portion AA of the semiconductor package of FIG. 1.

### DETAILED DESCRIPTION OF THE EMBODIMENTS

Hereinafter, embodiments of the inventive concept are described in detail with reference to the accompanying drawings. Like reference numerals are used for the same components in the drawings, and duplicate descriptions thereof are omitted.

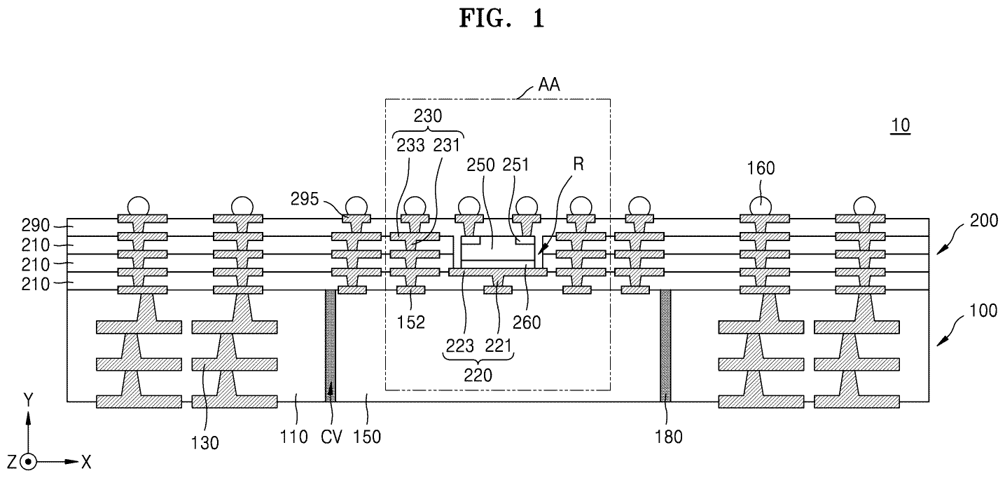

FIG. 1 is a schematic cross-sectional view of a semiconductor package 10 according to an embodiment.

Referring to FIG. 1, the semiconductor package 10 may include a first substrate 100, a first chip 150, a first redistribution structure 200, and a passive element 250. The first substrate 100 has an upper surface and a lower surface opposite to the upper surface, and at least one of the upper and lower surfaces may have a flat shape. In the following drawings, an X-axis direction and a Z-axis direction represent directions parallel to the upper surface of the first substrate 100. The X-axis direction and the Z-axis direction are perpendicular to each other. A Y-axis direction represents a direction perpendicular to the upper or lower surface of the first substrate 100. In other words, the Y-axis direction may be perpendicular to an X-Z plane.

A first horizontal direction may refer to the X-axis direction, a second horizontal direction may refer to the Z-axis direction, and a vertical direction may refer to the Y-axis direction.

The first substrate 100 is located below the first redistribution structure 200 and may include a body 110 and a wiring pattern 130 formed inside the body 110. The body 110 may include a plurality of layers, but it is not necessarily limited thereto. For example, the body 110 may be formed as a single unit and include only one layer. The wiring pattern 130 may be electrically connected to a second redistribution pattern 230 of the first redistribution structure 200. The wiring pattern 130 may have a tapered shape in which a horizontal width increases as a vertical level decreases. However, the shape of the wiring pattern 130 is not necessarily limited thereto. For example, the wiring pattern 130 may have a shape with the same horizontal width regardless of the vertical level, or may have a tapered shape in which the horizontal width narrows as the vertical level decreases.

The first substrate 100 may be formed of, for example, a ceramic substrate, a printed circuit board (PCB), or an organic substrate, but is not necessarily limited thereto. For example, the body 110 surrounding the wiring pattern 130 may include an insulating material. The wiring pattern 130 may include at least one material among copper, nickel, stainless steel, or beryllium copper, and the body 110 may include Frame Retardant 4 (FR-4), tetrafunctional epoxy, polyphenylene ether, epoxy/polyphenylene oxide, bismaleimide triazine (BT), thermount, cyanate ester, polyimide, or liquid crystal polymer.

The first substrate 100 may include a cavity CV penetrating the body 110 in the vertical direction (Y). The first chip 150 may be mounted inside the cavity CV. According to example embodiments, a footprint of the first chip 150 may be smaller than a footprint of the cavity CV. A side surface of the first chip 150 may be spaced apart from the first substrate 100 in the horizontal directions (X, Z) within the cavity CV. In other words, an empty space may be formed between the first chip 150 and the first substrate 100. A molding member 180 may fill the empty space formed between the first chip 150 and the first substrate 100. According to example embodiments, the molding member 180 may include a thermosetting resin, such as an epoxy resin, a thermoplastic resin, such as polyimide, or a resin including a reinforcing material, such as an inorganic filler, specifically, ajinomoto build-up film (ABF), FR-4, BT, etc.

The first chip 150 may include at least one of a memory chip and a logic chip. For example, the first chip 150 may be a memory chip or a logic chip, or may be a 3D stacked chip including both the memory chip and the logic chip. The memory chip may be, for example, a volatile memory chip, such as Dynamic Random Access Memory (DRAM) or Static Random Access Memory (SRAM), or a non-volatile memory chip, such as phase-change random access memory (PRAM), magnetoresistive random access memory (MRAM), ferroelectric random access memory (FeRAM), or resistive random access memory (RRAM). The logic chip may include, for example, a microprocessor, such as a central processing unit (CPU), a graphic processing unit (GPU), an application processor (AP), an analog element, or a digital signal processor. The 3D stacked chip may include a shape in which a memory chip and a logic chip are vertically stacked and connected through a through electrode.

A plurality of first chip pads 152 may be provided on an upper surface of the first chip 150. Some of the plurality of first chip pads 152 may be electrically connected to the first redistribution pattern 220 in the first redistribution structure 200, and some other of the plurality of first chip pads 152 may be electrically connected to the second redistribution pattern 230 in the first redistribution structure 200.

The first redistribution structure 200 may be located on the upper surface of the first substrate 100. The first redistribution structure 200 may include a redistribution insulating layer 210, the first redistribution pattern 220, the second redistribution pattern 230, a first insulating layer 290, and an under bump metal 295. According to example embodiments, the redistribution insulating layer 210 may be provided as a plurality of layers and may be provided by stacking each other in the vertical direction (Y). For example, the redistribution insulation layer 210 may be provided as three layers. The redistribution insulating layer 210 may include, for example, a photo imageable dielectric (PID) or photosensitive polyimide (PSPI).

The first redistribution structure 200 may have a recess R penetrating at least one of the plurality of redistribution insulating layers 210. The recess R may extend downward in the vertical direction (Y) from an uppermost redistribution insulating layer 210 among the plurality of redistribution insulating layers 210. According to example embodiments, the recess R has a shape extending in the vertical direction (Y) from the upper surface of the redistribution insulating layer 210 located at the top to an upper surface of the redistribution insulating layer 210 located at the bottom. However, the recess R is not necessarily limited thereto, and the recess R may not vertically extend to the upper surface of a lowermost redistribution insulating layer 210 if a depth of the recess R is sufficient enough to mount the passive element 250.

A cross-section of the recess R along the X-Z plane may have a shape that is substantially the same as or similar to a cross-section of the passive element 250 along the X-Z plane. For example, a cross-section of the recess R the passive element 250 along the X-Z plane may be a circular or polygonal shape.

The first redistribution pattern 220 and the second redistribution pattern 230 may be provided in the redistribution insulating layers 210. The first redistribution pattern 220 may be located below the recess R, and the second redistribution pattern 230 may be located adjacent to the recess R. The first redistribution pattern 220 and the second redistribution pattern 230 may include, for example, a metal or an alloy of metals, such as copper (Cu), aluminum (Al), tungsten (W), titanium (Ti), tantalum (Ta), and indium (In), molybdenum (Mo), manganese (Mn), cobalt (Co), tin (Sn), nickel (Ni), magnesium (Mg), rhenium (Re), beryllium (Be), gallium (Ga), ruthenium (Ru), etc., but is not necessarily limited thereto. For example, the first redistribution pattern 220 and the second redistribution pattern 230 may be formed by stacking a metal or metal alloy on a seed layer including Cu, Ti, titanium nitride, or titanium tungsten.

The first redistribution pattern 220 may include a first redistribution line pattern 223 and a first redistribution via pattern 221. The first redistribution line pattern 223 may extend in the first horizontal direction (X), and the first redistribution via pattern 221 may extend in the vertical direction (Y). The first redistribution line pattern 223 may have a shape extending in a horizontal direction (X) along the upper surface of at least one of the redistribution insulating layer 210 which the recess R does not penetrate through. For example, if the redistribution insulating layer 210 is provided in three layers and the recess R penetrates second and third redistribution insulating layer 210 in the vertical direction (Y), the first redistribution line pattern 223 may extend in the horizontal direction along the upper surface of the first redistribution insulating layer 210. The first redistribution line pattern 223 may be located immediately below the recess R and may have a flat shape. For example, the bottom end of the recess R may be in contact with the top surface of the first redistribution line pattern 223. The first redistribution via pattern 221 may extend through the redistribution insulating layer 210 below the first redistribution line pattern 223 in the vertical direction (Y). A footprint of the first redistribution line pattern 223 may be greater than a footprint of the recess R.

The first redistribution line pattern 223 may serve as a stopper in the process of forming the recess R penetrating the plurality of redistribution insulating layers 210, as described later. For example, when forming the recess R through laser processing, the laser may not pass through the first redistribution line pattern 223, and accordingly, the recess R may not be formed in the lower part of the first redistribution line pattern 223, and the recess R may be formed only in the upper part of the first redistribution line pattern 223.

The second redistribution pattern 230 may include a second redistribution line pattern 233 and a second redistribution via pattern 231. The second redistribution pattern 230 may be a multi-layer structure in which the second redistribution line pattern 233 and the second redistribution via pattern 231 are alternately stacked. The second redistribution line pattern 233 may extend in the horizontal direction along the upper and lower surfaces of at least one of the redistribution insulating layers 210. The second redistribution via pattern 231 may extend through the redistribution insulating layer 210 in the vertical direction (Y). The second redistribution via pattern 231 may electrically connect the second redistribution line patterns 233 located at different levels in the vertical direction (Y). In some embodiments, the second redistribution line patterns 233 and the second redistribution via patterns 231 may form a unified structure. For example, the unified structure of the first redistribution via pattern 221 and the second redistribution via pattern 231 may have a tapered shape in which a horizontal width narrows as the vertical level decreases.

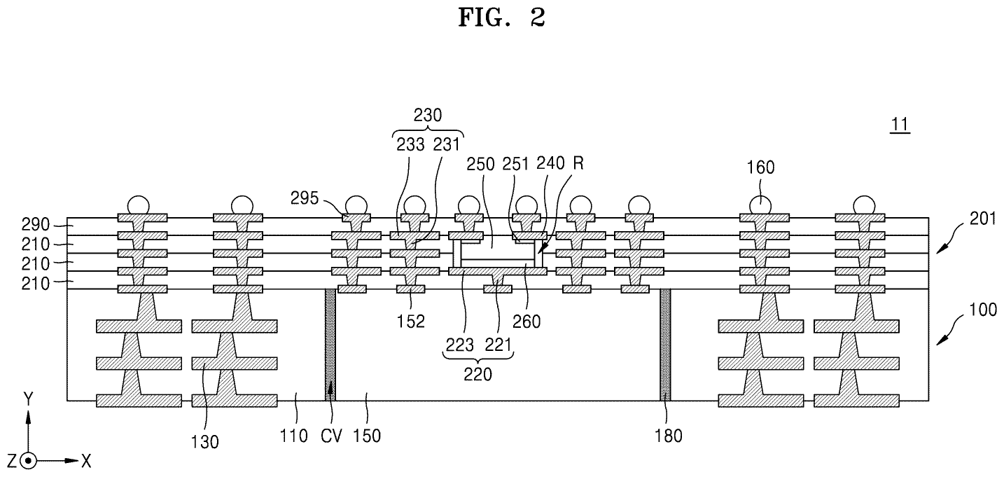

The passive element 250 may be mounted inside the recess R. According to example embodiments, side surfaces of the passive element 250 may be spaced apart from side surfaces of the redistribution insulation layer 210 formed by the recess R in the horizontal directions (X, Z). The passive element 250 may be located above the first redistribution line pattern 223. According to example embodiments, a footprint of the passive element 250 may be smaller than a footprint of the first redistribution line pattern 223. A metal layer 251 may be located on an upper surface of the passive element 250. The passive element 250 may be electrically connected to a conductive material through the metal layer 251. For example, the passive element 250 may be connected to the under-bump metal 295 formed in the first insulating layer 290 through the metal layer 251, or as described later, may be connected to a third redistribution pattern 240 (refer to FIG. 2). The passive element 250 may be electrically connected to the first chip 150 through at least one of the redistribution patterns 220 and 230 formed in the first redistribution structure 200 or may be electrically connected to an external device through the under-bump metal 295 and an external connection terminal 160.

According to example embodiments, the passive element 250 may overlap the first redistribution line pattern 223 in the vertical direction (Y). Additionally, the passive element 250 may overlap the first chip 150 in the vertical direction (Y).

According to example embodiments, the upper surface of the passive element 250 may be located at substantially the same vertical level as the upper surface of the uppermost redistribution insulating layer 210 or may be located at a lower vertical level than the upper surface of the uppermost redistribution insulating layer 210. However, the disclosure is not necessarily limited thereto, and in some embodiments, the upper surface of the passive element 250 may be located at a vertical level higher than the upper surface of the uppermost redistribution insulating layer 210. However, because the passive element 250 is covered by a first insulating layer 290, the upper surface of the passive element 250 may not be exposed to the outside.

The passive element 250 may be a capacitor or a resistor. For example, the passive element 250 may include a capacitor, such as an integrated stack capacitor (ISC), a multi-layer ceramic capacitor (MLCC), or a low inductance chip capacitor (LICC), an inductor, beads, etc.

An adhesive layer 260 may be interposed between the passive element 250 and the first redistribution pattern 220. For example, the adhesive layer 260 may be interposed between the passive element 250 and the first redistribution line pattern 223. The adhesive layer 260 may fix the passive element 250 provided inside the recess R. According to example embodiments, the adhesive layer 260 may be a film with adhesive properties. For example, the adhesive layer 260 may be a double-sided adhesive film. According to example embodiments, the adhesive layer 260 may include a tape-type material layer, a liquid-phase coating cured material layer, or a combination thereof. Additionally, the adhesive layer 260 may include a thermal setting structure, thermal plastic, an ultraviolet (UV cure material, or a combination thereof. The adhesive layer 260 may be referred to as die attach film (DAF) or non-conductive film (NCF).

The first insulating layer 290 may fill an empty space between the recess R and the passive element 250 and cover the upper surface of the redistribution insulating layer 210. For example, the first insulating layer 290 may cover the upper surface of the redistribution insulating layer 210 located at the top among the plurality of redistribution insulating layers 210. The first insulating layer 290 extends in the horizontal direction (X, Z) on the upper surface of the uppermost redistribution insulating layer 210 and may extend in the vertical direction (Y) in a region filling the recess R. The first insulating layer 290 may include an insulating material. For example, the first insulating layer 290 may include a thermosetting resin, such as an epoxy resin, a thermoplastic resin, such as polyimide, or a resin including a reinforcing material, such as an inorganic filler, specifically, an Ajinomoto Build-up Film (ABF), FR-4, BT, etc., but is not necessarily limited thereto.

The under-bump metal 295 may be formed inside or on the first insulating layer 290. The under-bump metal 295 may be electrically connected to the second redistribution pattern 230. The external connection terminal 160 may be electrically connected to the under-bump metal 295. The external connection terminal 160 may be electrically connected to an external device, for example, a motherboard. The external connection terminal 160 may electrically and physically connect the semiconductor package 10 and an external device. The external connection terminal 160 may include at least one of a conductive material, for example, solder, tin (Sn), silver (Ag), copper (Cu), or aluminum (Al).

The passive element 250 of the semiconductor package 10 according to an embodiment may be located within the first redistribution structure 200. For example, the passive element 250 may be located within the plurality of redistribution insulating layers 210 and adjacent to the first insulating layer 290. For example, the passive element 250 may be at least partially surrounded by the plurality of redistribution insulating layers 210 and the first insulating layer 290, and thus protected from external impact.

In addition, because the passive element 250 is fixed to the upper part of the first redistribution line pattern 223 by the adhesive layer 260, and the side and upper surfaces of the passive element 250 are covered by the first insulating layer 290, an underfill process for mounting the passive element 250 may be omitted. Accordingly, the process may be simplified.

FIG. 2 is a schematic cross-sectional view showing a semiconductor package 11 according to an embodiment. To the extent that details are not described, it may be assumed that the elements are at least similar to corresponding elements described in FIG. 1.

Referring to FIG. 2, the semiconductor package 11 may include a first substrate 100, a first chip 150, a first redistribution structure 201, and a passive element 250. The first substrate 100 may include a body 110 and a wiring pattern 130 formed inside the body 110. A cavity CV penetrating through the body 110 may be formed in the body 110 extending in the vertical direction (Y). The first chip 150 is mounted inside the cavity CV. A side surface of the first chip 150 may be spaced apart from the first substrate 100 in the horizontal directions (X, Z) within the cavity CV. A molding member 180 may fill the empty space between the first chip 150 and the first substrate 100.

A first redistribution structure 201 may be located on an upper surface of the first substrate 100 and the first chip 150. The first redistribution structure 201 includes redistribution insulating layers 210, a first redistribution pattern 220, a second redistribution pattern 230, a third redistribution pattern 240, and a first insulating layer 290, and may include an under-bump metal 295.

The redistribution insulating layer 210 may be provided as a plurality of layers and may be provided by stacking each other in the vertical direction (Y). For example, the redistribution insulation layer 210 may be provided as three layers.

The first redistribution structure 201 may have a recess R penetrating at least one of the plurality of redistribution insulating layers 210. The recess R may extend downward in the vertical direction (Y) from an upper surface of the uppermost redistribution insulating layer 210 among the plurality of redistribution insulating layers 210.

The first redistribution pattern 220 and the second redistribution pattern 230 may be provided in the redistribution insulating layer 210. The third redistribution pattern 240 may be provided within the first insulating layer 290. The first redistribution pattern 220 may be located at a bottom of the recess R, the second redistribution pattern 230 may be located on a side of the horizontal direction (X, Z) of the recess R, and the third redistribution pattern 240 may be located on the recess R. The third redistribution pattern 240 may be located on the passive element 250.

The first redistribution pattern 220 may include a first redistribution line pattern 223 and a first redistribution via pattern 221. The second redistribution pattern 230 may include a second redistribution line pattern 233 and a second redistribution via pattern 231. The third redistribution pattern 240 may include a third redistribution line pattern. In some embodiments, the third redistribution pattern 240 may further include a third redistribution via pattern.

The first insulating layer 290 may fill an empty space between the recess R and the passive element 250 and cover the upper surface of the redistribution insulating layer 210. The first insulating layer 290 may cover the third redistribution pattern 240. The under-bump metal 295 may be formed inside the first insulating layer 290.

The passive element 250 may be electrically connected to the first chip 150 or an external device. According to example embodiments, the passive element 250 may be electrically connected to the first chip 150 through the second redistribution pattern 230 and the third redistribution pattern 240. If the third redistribution pattern 240 includes only a third redistribution line pattern, the third redistribution line pattern may physically contact the metal layer 251 of the passive element 250, and thus, the third redistribution line pattern and the passive element 250 may be electrically connected to each other. If the third redistribution pattern 240 further includes a third redistribution via pattern, the third redistribution via pattern may physically contact the metal layer 251 of the passive element 250, and thus, the third redistribution via pattern and the passive element 250 may be electrically connected to each other. The third redistribution pattern 240 may be electrically connected to the second redistribution pattern 230. The second redistribution pattern 230 may be electrically connected to the first chip 150. As a result, the passive element 250 may be directly connected to the first chip 150 through the third redistribution pattern 240 and the second redistribution pattern 230.

According to example embodiments, the third redistribution line pattern may be spaced apart from the second redistribution line pattern 233 in the horizontal direction (X, Z). In some embodiments, the third redistribution line pattern may physically contact the second redistribution line pattern 233 in the horizontal direction (X, Z).

The passive element 250 may be electrically connected to the first chip 150 through the second redistribution pattern 230 and the third redistribution pattern 240 while being inside the redistribution insulating layer 210 and the first insulating layer 290.

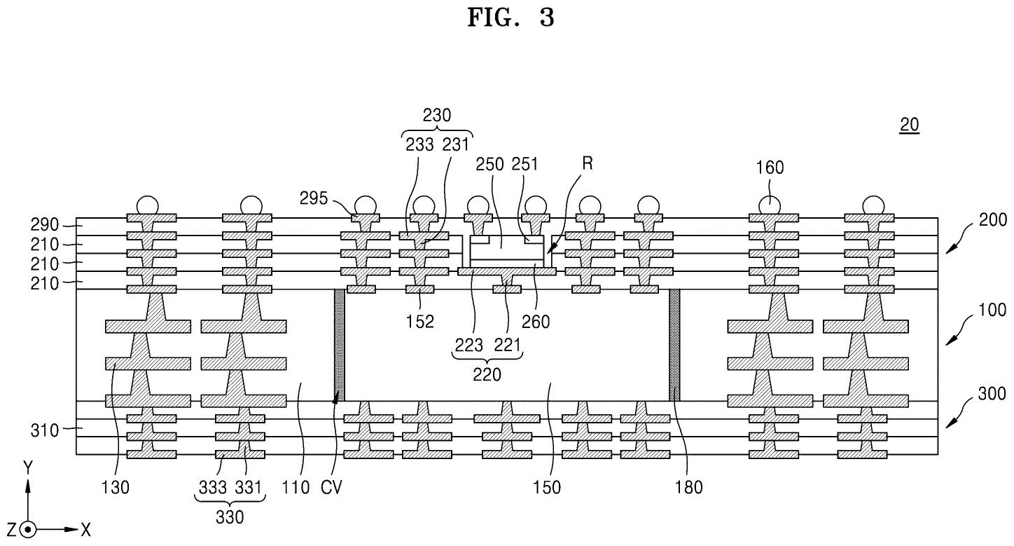

FIG. 3 is a schematic cross-sectional view showing a semiconductor package 20 according to an embodiment. To the extent that details are not described, it may be assumed that the elements are at least similar to corresponding elements described in FIG. 1.

Referring to FIG. 3, the semiconductor package 20 may include a first substrate 100, a first chip 150, a first redistribution structure 200, a second redistribution structure 300, and a passive element 250. The first substrate 100 may include a body 110 and a wiring pattern 130 formed inside the body 110. A cavity CV may be formed in the body 110 and penetrate the body 110 in a vertical direction (Y). The first chip 150 is mounted inside the cavity CV, and a molding member 180 may fill an empty space between the first chip 150 and the first substrate 100.

The first redistribution structure 200 may be located on upper surfaces of the first substrate 100 and the first chip 150. The first redistribution structure 200 may include a redistribution insulating layer 210, a first redistribution pattern 220, a second redistribution pattern 230, a first insulating layer 290, and an under-bump metal 295. The redistribution insulating layer 210 may be provided as a plurality of layers and may be provided by stacking each other in the vertical direction (Y). For example, the redistribution insulation layer 210 may be provided as three layers. The first redistribution pattern 220 and the second redistribution pattern 230 may be provided in the redistribution insulating layer 210. The first redistribution pattern 220 includes a first redistribution line pattern 223 and a first redistribution via pattern 221, and the second redistribution pattern 230 includes a second redistribution line pattern 233 and a second redistribution via pattern 231. The first insulating layer 290 may fill an empty space between a recess R and the passive element 250 and cover an upper surface of the redistribution insulating layer 210. The under-bump metal 295 may be formed inside the first insulating layer 290.

The second redistribution structure 300 may be located below the first substrate 100. The second redistribution structure 300 may include a redistribution insulating layer 310 and a fourth redistribution pattern 330. The fourth redistribution pattern 330 may be electrically connected to the wiring pattern 130 of the first substrate 100. In some embodiments, the fourth redistribution pattern 330 may be electrically connected to the first chip 150. The fourth redistribution pattern 330 may include a fourth redistribution via pattern 331 and a fourth redistribution line pattern 333.

According to example embodiments, at least one semiconductor chip may be mounted on a lower part of the second redistribution structure 300. For example, two semiconductor chips may be mounted on the lower part of the second redistribution structure 300. The semiconductor chips may be electrically connected to the fourth redistribution pattern 330. According to example embodiments, the semiconductor chips may be of the same type or of different types.

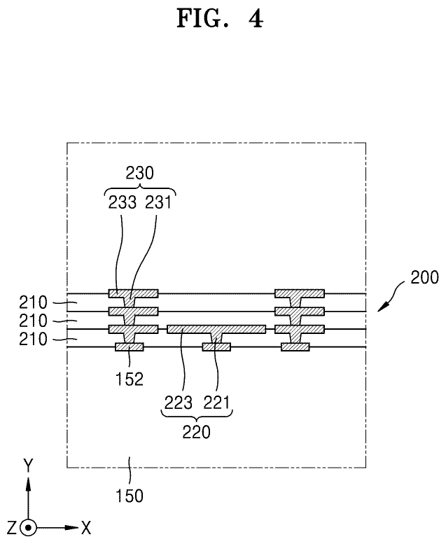

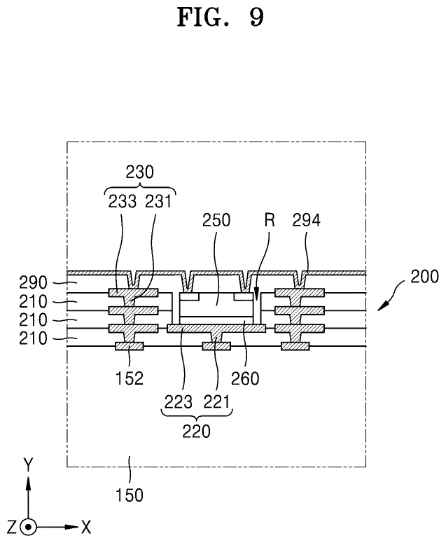

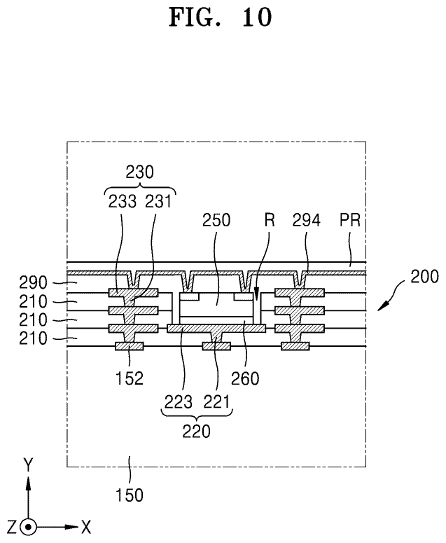

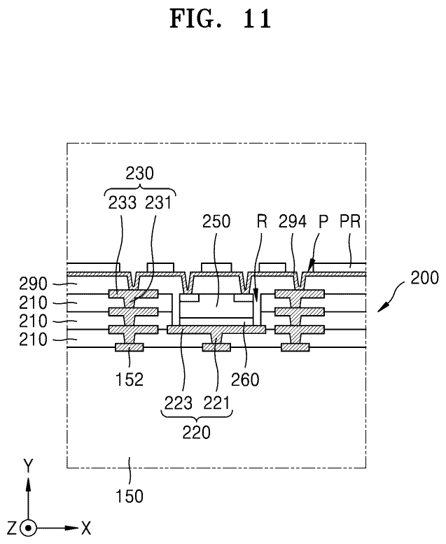

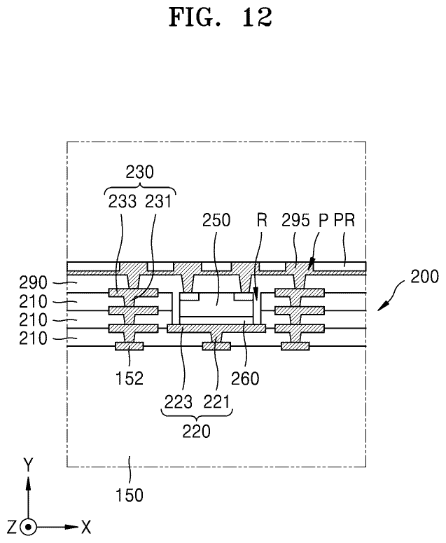

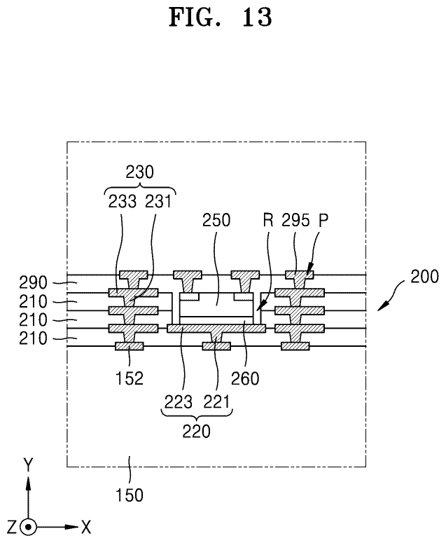

FIGS. 4 to 13 are schematic cross-sectional views showing a method of manufacturing a portion AA of the semiconductor package 10 of FIG. 1. To the extent that details are not described, it may be assumed that the elements are at least similar to corresponding elements described in FIG. 1.

Referring to FIG. 4, a plurality of redistribution insulating layers 210 are formed on an upper surface of the first chip 150 including a first chip pad 152. A first redistribution pattern 220 and a second redistribution pattern 230 are formed in the first redistribution insulating layers 210.

One layer of a redistribution insulating layer 210 is formed on an upper surface of the first chip 150, and the first redistribution pattern 220 and the second redistribution pattern 230 may be formed by etching the redistribution insulating layer 210. Afterwards, a redistribution insulating layer 210 covering the redistribution insulating layer 210, the first redistribution pattern 220, and the second redistribution pattern 230 is formed, and then the redistribution insulating layer 210 is etched to form the second redistribution pattern 230. Afterwards, a redistribution insulating layer 210 covering the redistribution insulating layer 210 and the second redistribution pattern 230 is formed, and the redistribution insulating layer 210 is etched to form a second redistribution pattern 230. Through this process, three layers of the second redistribution pattern 230 may be formed, and one layer of the first redistribution pattern 220 may be formed. However, the number of layers of the first redistribution pattern 220 and the second redistribution pattern 230 is not necessarily limited thereto. The first redistribution pattern 220 and the second redistribution pattern 230 might not overlap each other in the vertical direction (Y). In other words, only the redistribution insulating layers 210 are located on the first redistribution pattern 220 and might not overlap the second redistribution pattern 230 in the vertical direction (Y).

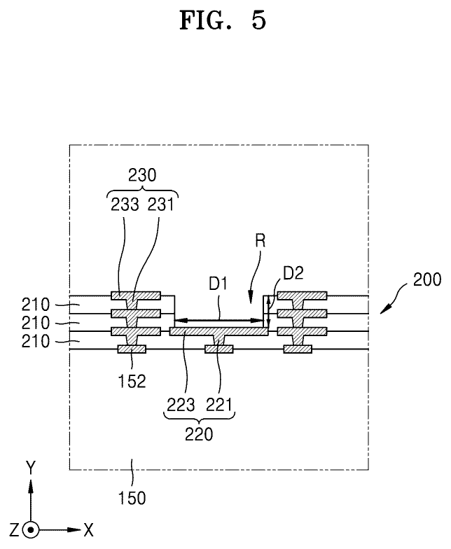

Referring to FIG. 5, the redistribution insulating layers 210 are etched in the vertical direction (Y), exposing an upper surface of the first redistribution pattern 220 and forming a recess R. At this time, a width of the recess R in the first horizontal direction (X) may be in a range from about 500 μm to about 900 μm. Additionally, a depth of the recess R in the vertical direction (Y) may be in a range from about 100 μm to about 200 μm. The formation of the recess R may be achieved through an etching process by using a laser or drilling. However, the method of forming the recess R is not necessarily limited thereto. The first redistribution line pattern 223 may serve as a stopper in a process of forming the recess R. In other words, when etching the redistribution insulating layers 210 using a laser, etc., the first redistribution line pattern 223 may prevent the redistribution insulating layer 210 located below the first redistribution line pattern 223 from being etched. The recess R may be formed between inner sides of the first redistribution line pattern 223. The recess R may be formed from an upper surface of the uppermost redistribution insulating layer 210 among the plurality of redistribution insulating layers 210 to an upper surface of the first redistribution line pattern 223.

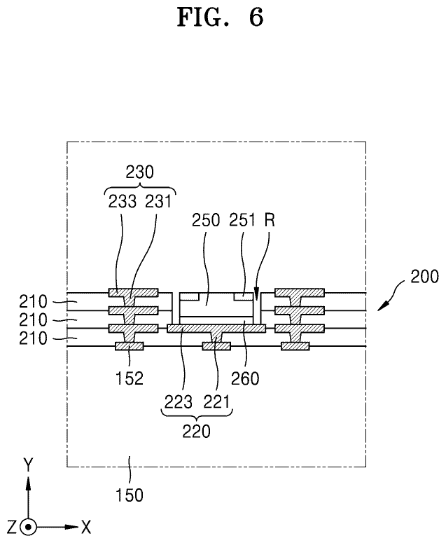

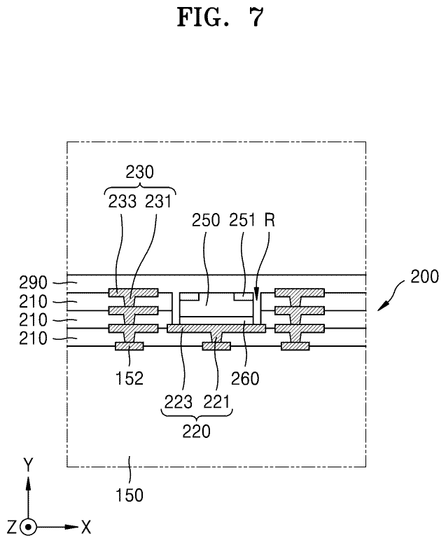

Referring to FIGS. 6 and 7, a passive element 250 is mounted inside the recess R. The passive element 250 may be fixed on the first redistribution line pattern 223 through an adhesive layer 260. Thereafter, a first insulating layer 290 may be applied to cover upper surfaces of the passive element 250 and the redistribution insulating layer 210. At this time, the redistribution insulating layer 210 covered by the first insulating layer 290 may be the uppermost redistribution insulating layer 210 among the plurality of redistribution insulating layers 210.

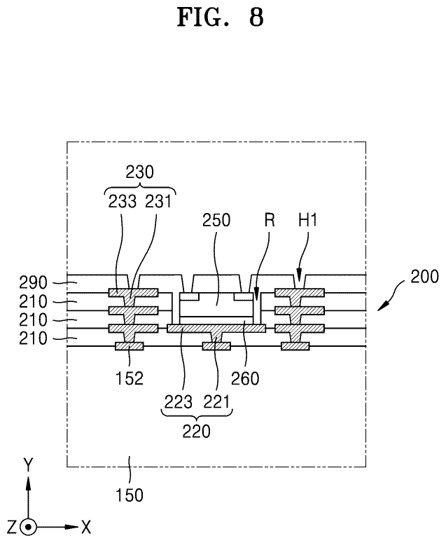

Referring to FIGS. 8 to 13, a first hole H1 is formed by etching the first insulating layer 290 to match a position where an under-bump metal 295 is to be formed, and a seed layer 294 covering the first hole H1 is formed. Afterwards, a photo resist PR covering the seed layer 294 is applied, and a pattern P is formed on the photo resist PR. Thereafter, the pattern P is filled with under-bump metal 295, and, after removing the seed layer 294 located outside the pattern P, the photo resist PR is removed to form an under-bump metal 295.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first substrate having an upper surface and a lower surface and a cavity extending from the upper surface to the lower surface;
a first chip mounted in the cavity;
a first redistribution structure disposed on the first chip;
a passive element mounted inside the first redistribution structure; and
an adhesive layer disposed below the passive element,
wherein the first redistribution structure includes a plurality of redistribution insulating layers stacked in a vertical direction on the first chip, and a first redistribution pattern and a second redistribution pattern located within the redistribution insulating layers,
wherein the first redistribution pattern is disposed below a recess vertically penetrating at least one redistribution insulating layer among the plurality of redistribution insulating layers, and
wherein the second redistribution pattern is adjacent to the recess in a lateral direction.

2. The semiconductor package of claim 1, wherein
the first redistribution structure further includes a first insulating layer covering an upper surface of an uppermost redistribution insulating layer among the plurality of redistribution insulating layers, side and upper surfaces of the passive element and an under-bump metal formed in the first insulating layer.

3. The semiconductor package of claim 2, wherein the first insulating layer is in contact with the first redistribution pattern.

4. The semiconductor package of claim 1, wherein
the first redistribution pattern includes a first redistribution line pattern and a first redistribution via pattern, and
wherein a footprint of the first redistribution line pattern is greater than a footprint of the recess.

5. The semiconductor package of claim 1, wherein a width of the recess in a horizontal direction is about 500 μm to about 900 μm.

6. The semiconductor package of claim 1, wherein a depth of the recess in the vertical direction is about 100 μm to about 200 μm.

7. The semiconductor package of claim 1, wherein
the plurality of redistribution insulating layers includes three layers,
wherein the first redistribution pattern is disposed in the lowermost redistribution insulating layer, and
wherein the second redistribution pattern is disposed in each of the three redistribution insulating layers.

8. The semiconductor package of claim 1, wherein the passive element overlaps the first chip in the vertical direction.

9. The semiconductor package of claim 1, wherein
a third redistribution pattern is disposed on the passive element, and
wherein the passive element is electrically connected to the first chip through the third redistribution pattern and the second redistribution pattern.

10. The semiconductor package of claim 1, further comprising a molding member covering a side surface of the first chip.

11. The semiconductor package of claim 1, further comprising a second redistribution structure disposed below the first substrate.

12. A semiconductor package comprising:
a first substrate with a cavity extending from an upper surface of the first substrate to a lower surface of the first substrate;
a first chip mounted in the cavity;
a first redistribution structure disposed on the first substrate and the first chip;
a passive element mounted inside the first redistribution structure; and
an adhesive layer disposed below the passive element,
wherein the first redistribution structure includes a plurality of redistribution insulating layers stacked in a vertical direction on the first chip, a first redistribution pattern and a second redistribution pattern disposed within the redistribution insulating layers, and a first insulating layer covering an uppermost redistribution insulating layer among the plurality of redistribution insulating layers and the passive element,
wherein the first redistribution pattern is disposed below a recess vertically penetrating at least one redistribution insulating layer among the plurality of redistribution insulating layers,
wherein the second redistribution pattern is disposed adjacent to the recess in a lateral direction, and
wherein an upper surface of the passive element is disposed at a lower level than an upper surface of the uppermost redistribution insulating layer.

13. The semiconductor package of claim 12, wherein
the first redistribution pattern includes a first redistribution line pattern and a first redistribution via pattern, and
wherein the first insulating layer contacts the first redistribution line pattern.

14. The semiconductor package of claim 13, wherein
a footprint of the first redistribution line pattern is greater than a footprint of the recess, and the footprint of the recess is greater than a footprint of the passive element.

15. The semiconductor package of claim 12, wherein a width of the recess is about 500 μm to about 900 μm.

16. The semiconductor package of claim 15, wherein a depth of the recess is about 100 μm to about 200 μm.

17. The semiconductor package of claim 1, wherein
a third redistribution pattern is disposed in the first insulating layer,
wherein the third redistribution pattern is disposed on the passive element, and
wherein the passive element is electrically connected to the first chip through the third redistribution pattern and the second redistribution pattern.

18. A semiconductor package comprising:
a first substrate with a cavity extending from an upper surface of the first substrate to a lower surface of the first substrate;
a first chip mounted in the cavity;
a first redistribution structure disposed on the first substrate and the first chip;
a passive element mounted inside the first redistribution structure;
an adhesive layer disposed below the passive element; and
a second redistribution structure disposed below the first substrate,
wherein the first redistribution structure includes a plurality of redistribution insulating layers stacked in a vertical direction on the first chip, a first redistribution pattern and a second redistribution pattern disposed within the redistribution insulating layers, and a first insulating layer covering an uppermost redistribution insulating layer among the plurality of redistribution insulating layers and the passive element,
wherein the first redistribution pattern is disposed below a recess vertically penetrating in at least one redistribution insulating layer among the plurality of redistribution insulating layers,
wherein the second redistribution pattern is disposed adjacent to the recess,
wherein an upper surface of the passive element is disposed at a lower level than an upper surface of the uppermost redistribution insulating layer, and
wherein a width of the recess is about 500 μm to about 900 μm, and a depth of the recess is about 100 μm to about 200 μm.

19. The semiconductor package of claim 18, wherein
the first redistribution pattern includes a first redistribution line pattern and a first redistribution via pattern,
wherein the first insulating layer is in contact with the first redistribution line pattern, and
wherein a footprint of the first redistribution line pattern is greater than a footprint of the recess, and the footprint of the recess is greater than a footprint of the passive element.

20. The semiconductor package of claim 18, wherein
a third redistribution pattern is disposed in the first insulating layer,
wherein the third redistribution pattern is disposed on the passive element, and
wherein the passive element is electrically connected to the first chip through the third redistribution pattern and the second redistribution pattern.
